(19) United States
(12) Patent Application Publication
(10) Pub. No.: US 2007/0069637 A1
(43) Pub. Date: Mar. 29, 2007

(54) Polymer light emitting diode having interinsulation layer and method for fabricating the same

(75) Inventors: Jin Jang, Seoul (KR); Yong-Kyun Lee, Seoul (KR)

Correspondence Address: DALY, CROWLEY, MOFFORD & DURKEE, LLP, SUITE 301A, 354A TURNPIKE STREET, CANTON, MA, 02021-2714, US

(73) Assignee: JIN JANG

(21) Appl. No.: 11/321,703

(22) Filed: Dec. 29, 2005

(30) Foreign Application Priority Data
Sep. 28, 2005 (KR) 10-2005-0090472

(51) Int. Cl. H05B 33/00; H01J 1/62

(52) U.S. Cl. 313/504; 313/506

(57) ABSTRACT

A polymer light emitting diode having an interinsulation layer between a hole injecting layer (or a hole transporting layer) and a light emitting polymer layer, and a method for fabricating the polymer light emitting diode. The polymer light emitting diode having the interinsulation layer includes a hole injecting layer formed on an anode layer, formed on a glass substrate, by coating or printing; the interinsulation layer having a designated thickness formed on the hole injecting layer; a light emitting polymer layer formed on the interinsulation layer by coating or printing; and an electron injecting layer formed on the light emitting polymer layer, and a cathode layer formed on the electron injecting layer.

### CROSS REFERENCE TO RELATED APPLICATION

The present application claims priority to Korean Patent Application No. 10-2005-0090472 filed on Sep. 28, 2005, which is incorporated herein by reference.

### BACKGROUND OF THE INVENTION

1. Field of the Invention

The present invention relates to a polymer light emitting diode and a method for fabricating the same, and more particularly to a polymer light emitting diode having OTS interinsulation layer (interlayer insulating layer) made of OTS between a hole injecting layer (or a hole transporting layer) and a light emitting polymer layer and a method for fabricating the polymer light emitting diode.

2. Description of the Related Art

A polymer light emitting diode, which has π-conjugate bridges, has a high response speed, a low power consumption rate, and a simple fabricating process, thus becoming the focus of public attention. Intensive research of the polymer light emitting diode during the past several years results in remarkable development of technical factors, such as efficiency, durability, and color purity.

Injection of electric charges into an interface between an anode made of Indium Tin Oxide (ITO) and a light emitting polymer is one of problems in terms of performance and stability of a device. P. K. H. Ho announced a device employing a Self-Assembled Monolayer (SAM) made of a conductive polymer, a semiconductive polymer, or an insulating polymer and formed on an anode made of ITO for controlling the injection of electric charges (Adv. Mater. 10, 769 (1998)).

By employing the SAM, electric charges injected into a light emitting polymer layer are well harmonized, thereby improving the efficiency of the device. J. E. Malinsky announced the performance of a device employing an octadecyltrichlorosilane (OTS) layer on an ITO layer (Adv. Mater. 11, 227 (1999)).

H. Yan discloses a SAM made of a material having hole transporting characteristics, such as siloxane-derivatized, 4,4′-[(p-tricholorosilylpropylphenyl)phenyl-amino]biphenyl (TPD-Si₂), and formed on an anode made of ITO, thereby improving the efficiency of a device (Adv. Mater. 15, 835 (2003)).

In an organic light emitting diode, a SAM based on siloxane forms a dielectric layer without pores, and restrains the reaction between the anode made of ITO and a hole transporting layer.

Recently, H. Yan (Adv. Mater. 16, 1948 (2004)) and J. S. Kim (Appl. Phys. Lett. 87, 023506 (2005)) announced the performance of a polymer light emitting diode, into which an interlayer (intermediate layer) is inserted by spin-coating a solution between a poly(3,4-ethylenedioxythiophene)-poly-(styrenesulfonate) (PEDOT:PSS) layer and a light emitting polymer layer. The interlayer prevents electrons from flowing towards the PEDOT:PSS layer, or reduces luminescence quenching on an interface between the PEDOT:PSS layer and the interlayer.

Differing from the above conventional techniques, a polymer light emitting diode having an interinsulation layer made of OTS, which is used to improve an organic thin film transistor (OTFT) and has insulating characteristics, and formed between a PEDOT:PSS layer and a light emitting polymer layer using a SAM technique has been required.

### SUMMARY OF THE INVENTION

Therefore, the present invention has been made in view of the above problems, and it is an object of the present invention to provide a polymer light emitting diode having an interinsulation layer made of OTS, which is formed on a PEDOT:PSS hole injecting layer (or hole transporting layer) by a SAM technique.

It is another object of the present invention to provide a method for fabricating a polymer light emitting diode, in which an interinsulation layer made of OTS is formed between a PEDOT:PSS hole injecting layer (or hole transporting layer) and a light emitting polymer layer by a SAM technique.

In accordance with one aspect of the present invention, the above and other objects can be accomplished by the provision of a polymer light emitting diode having an interinsulation layer comprising: a hole injecting layer formed on an anode layer, formed on a glass substrate, by coating or printing; the interinsulation layer having a designated thickness formed on the hole injecting layer; a light emitting polymer layer formed on the interinsulation layer by coating or printing; and an electron injecting layer formed on the light emitting polymer layer, and a cathode layer formed on the electron injecting layer.

In accordance with a further aspect of the present invention, there is provided a polymer light emitting diode having an interinsulation layer comprising: a hole transporting layer formed on an anode layer, formed on a glass substrate, by coating or printing; the interinsulation layer having a designated thickness formed on the hole transporting layer; a light emitting polymer layer formed on the interinsulation layer by coating or printing; and an electron injecting layer formed on the light emitting polymer layer, and a cathode layer formed on the electron injecting layer. That is, the polymer light emitting diode comprises the hole transporting layer in place of the hole injecting layer, and the interinsulation layer formed on the hole transporting layer.

In accordance with another aspect of the present invention, there is provided a polymer light emitting diode having an interinsulation layer comprising: a hole injecting layer formed on an anode layer, formed on a glass substrate, by coating or printing; the interinsulation layer having a designated thickness formed on the hole injecting layer; a hole transporting layer formed on the interinsulation layer by coating or printing; a light emitting polymer layer formed on the hole transporting layer by coating or printing; and an electron injecting layer formed on the light emitting polymer layer, and a cathode layer formed on the electron injecting layer. That is, the polymer light emitting diode comprises the hole transporting layer and the hole injecting layer and the interinsulation layer formed between the hole transporting layer and the hole injecting layer.

In accordance with another aspect of the present invention, there is provided a polymer light emitting diode having an interinsulation layer comprising: a hole injecting layer formed on an anode layer, formed on a glass substrate, by coating or printing; a hole transporting layer formed on the hole injecting layer by coating or printing; the interinsulation layer having a designated thickness formed on the hole transporting layer; a light emitting polymer layer formed on the interinsulation layer by coating or printing; and an electron injecting layer formed on the light emitting polymer layer, and a cathode layer formed on the electron injecting layer. That is, the polymer light emitting diode comprises the hole injecting layer, the hole transporting layer formed on the hole injecting layer, and the interinsulation layer formed on the hole transporting layer.

The interinsulation layer may be formed by SAM treatment.

In accordance with another aspect of the present invention, there is provided a method for fabricating a polymer light emitting diode having an interinsulation layer comprising: forming a hole injecting layer on an anode layer, formed on a glass substrate, by coating or printing; forming the interinsulation layer having a designated thickness on the hole injecting layer; forming a light emitting polymer layer on the interinsulation layer by coating or printing; and sequentially forming an electron injecting layer and a cathode layer on the light emitting polymer layer.

In accordance with another aspect of the present invention, there is provided a method for fabricating a polymer light emitting diode having an interinsulation layer comprising: forming a hole transporting layer on an anode layer, formed on a glass substrate, by coating or printing; forming the interinsulation layer having a designated thickness on the hole transporting layer; forming a light emitting polymer layer on the interinsulation layer by coating or printing; and sequentially forming an electron injecting layer and a cathode layer on the light emitting polymer layer.

In accordance with another aspect of the present invention, there is provided a method for fabricating a polymer light emitting diode having an interinsulation layer comprising: forming a hole injecting layer on an anode layer, formed on a glass substrate, by coating or printing; forming the interinsulation layer having a designated thickness on the hole injecting layer; forming a hole transporting layer on the interinsulation layer by coating or printing; forming a light emitting polymer layer on the hole transporting layer by coating or printing; and sequentially forming an electron injecting layer and a cathode layer on the light emitting polymer layer.

In accordance with yet another aspect of the present invention, there is provided a method for fabricating a polymer light emitting diode having an interinsulation layer comprising: forming a hole injecting layer on an anode layer, formed on a glass substrate, by coating or printing; forming a hole transporting layer on the hole injecting layer by coating or printing; forming the interinsulation layer having a designated thickness on the hole transporting layer; forming a light emitting polymer layer on the interinsulation layer by coating or printing; and sequentially forming an electron injecting layer and a cathode layer on the light emitting polymer layer.

The interinsulation layer may be formed by SAM treatment.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a sectional view of a polymer light emitting diode in accordance with a first embodiment of the present invention;

FIG. 2 is a sectional view of a polymer light emitting diode in accordance with a second embodiment of the present invention;

FIG. 3 is a sectional view of a polymer light emitting diode in accordance with a third embodiment of the present invention;

FIG. 4 is a sectional view of a polymer light emitting diode in accordance with a fourth embodiment of the present invention;

FIGS. 5A to 5C are photographs of water contact angles for verifying whether or not an OTS interinsulation layer is formed in accordance with the present invention;

FIG. 6 illustrates graphs representing the relation among current, voltage and luminance of a polymer light emitting diode with an OTS interinsulation layer in accordance with the present invention and a polymer light emitting diode without an OTS interinsulation layer; and

FIG. 7 illustrates graphs representing current efficiency and power efficiency in proportion to voltage of a polymer light emitting diode with an OTS interinsulation layer in accordance with the present invention and a polymer light emitting diode without an OTS interinsulation layer.

### DESCRIPTION OF THE PREFERRED EMBODIMENTS

Now, polymer light emitting diodes having an interinsulation layer and methods for fabricating the same in accordance with preferred embodiments of the present invention will be described in detail with reference to the annexed drawings.

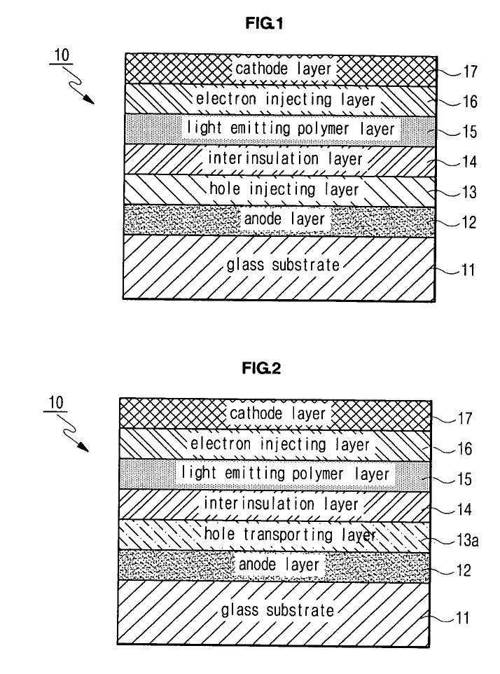

FIG. 1 is a sectional view of a polymer light emitting diode in accordance with a first embodiment of the present invention.

As shown in FIG. 1, the polymer light emitting diode 10 in accordance with the first embodiment comprises a glass substrate 11, an anode layer 12 formed on the glass substrate 11, a hole injecting layer 13 formed on the anode layer 12 by coating or printing, an interinsulation layer 14 having a designated thickness formed on the hole injecting layer 13, a light emitting polymer layer 15 formed on the interinsulation layer 14 by coating or printing, and an electron injecting layer 16 and a cathode layer 17 sequentially formed on the light emitting polymer layer 15.

The anode layer 12 formed on the glass substrate 11 is made of a material having a high work function, such as Indium Tin Oxide (ITO), thus easily receiving electrons at small energy. The hole injecting layer (HIL) 13 formed on the anode layer 12 by coating or printing facilitates the injection of holes from the anode layer 12 into the light emitting polymer layer 15.

The interinsulation layer 14 having the designated thickness formed on the HIL 13 is used to improve performance of an Organic Thin Film Transistor (OTFT), and has insulating characteristics. The interinsulation layer 14 is formed by SAM treatment.

The interinsulation layer 14 is made of an organic substance. Preferably, the organic substance is octadecyltrichlorosilane (OTS).

The light emitting polymer layer 15 formed on the interinsulation layer 14 by coating or printing serves to emit light, and the electron injecting layer 16 formed on the light emitting polymer layer 15 facilitates the injection of electrons from the cathode layer 17 into the light emitting polymer layer 15. Preferably, the electron injecting layer 16 is made of lithium fluoride (LiF), and the cathode layer 17 is made of aluminum.

Hereinafter, a process for fabricating the above polymer light emitting diode in accordance with the first embodiment will be described.

First, the anode layer 12 is formed on the glass substrate 11, and the HIL 13 made of PEDOT:PSS is formed on the anode layer 12 by coating or printing.

Thereafter, the interinsulation layer 14 having a designated thickness is formed on the HIL 13 by SAM treatment. Preferably, the interinsulation layer 14 is obtained by SAM treatment using a solution. That is, the interinsulation layer 14 is formed on the HIL 13 by soaking a device, obtained by sequentially forming the anode layer 12 and the HIL 13 on the glass substrate 11, in a solution for performing the SAM treatment.

The interinsulation layer 14 may have a mono-layered structure or at least a double-laminated structure. In order to form the interinsulation layer 14 having a mono-layered structure, it is preferable that the SAM treatment is carried out using an OTS solution. Preferably, the OTS solution has a concentration of 10˜100 mM, and the obtained interinsulation layer 14 has a thickness of 0.5˜5□. Further, preferably, the interinsulation layer 14 contains oxygen or carbon.

In order to form the interinsulation layer 14 having at least a double-laminated structure, the SAM treatment using the OTS solution is repeated at least twice, or the SAM treatment using the OTS solution and the SAM treatment using at least one other solution are carried out at least twice.

For example, the SAM treatment is first performed by soaking the device in the OTS solution, and the SAM treatment is performed one more time by soaking the device in one other solution, thereby forming the interinsulation layer 14 having at least a double-laminated structure.

In the case that the interinsulation layer 14 having at least a double-laminated structure is formed by the SAM treatment using the OTS solution and at least one other solution, preferably, the OTS solution and at least one other solution each has a concentration of 10˜100 mM, and the obtained interinsulation layer 14 has a thickness of 0.5˜5□. Further, preferably, the interinsulation layer 14 contains oxygen or carbon.

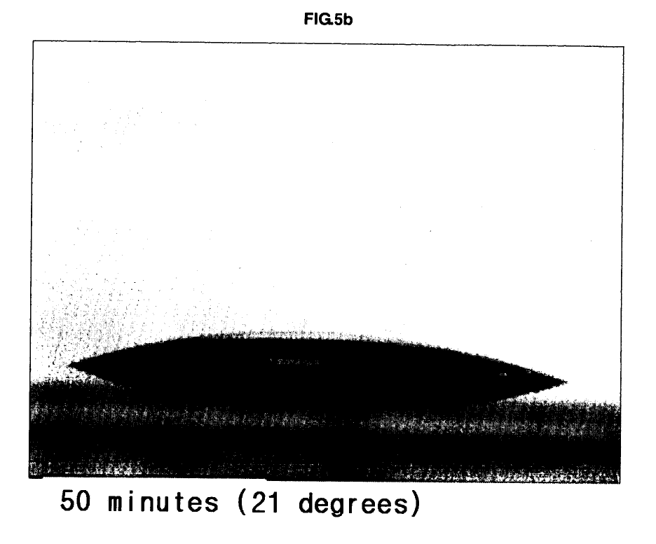

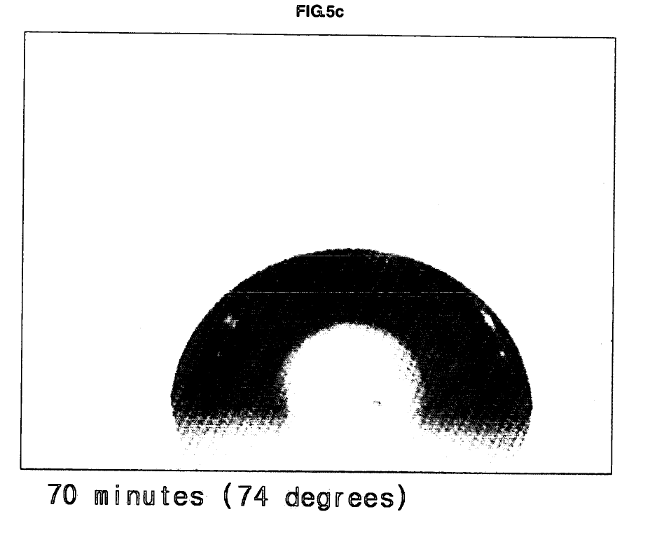

FIGS. 5A to 5C are photographs of water contact angles for verifying whether or not an OTS interinsulation layer is formed in proportion to time for SAM treatment.

FIG. 5A is a photograph of a glass substrate when 5 minutes from the start of the SAM treatment has elapsed, FIG. 5B is a photograph of the glass substrate when 50 minutes from the start of the SAM treatment has elapsed, and FIG. 5C is a photograph of the glass substrate when 70 minutes from the start of the SAM treatment has elapsed.

As shown in FIG. 5A, when 10 minutes from the start of the SAM treatment has elapsed, the water contact angle was approximately 6 degrees. As shown in FIG. 5B, when 50 minutes from the start of the SAM treatment has elapsed, the water contact angle was approximately 21 degrees and the surface of the hole injecting layer 13, on which the interinsulation layer 14 will be formed, still had a hydrophilic property. As shown in FIG. 5C, when 70 minutes from the start of the SAM treatment has elapsed, the water contact angle was approximately 74 degrees and the interinsulation layer 14 was formed on the hole injecting layer 13.

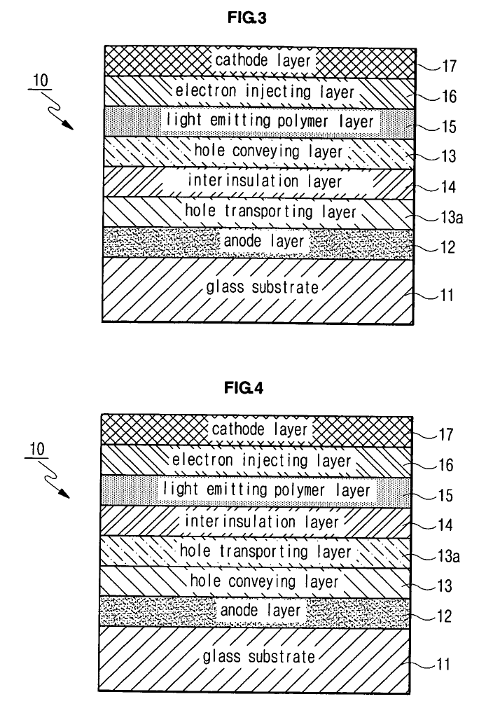

FIG. 2 is a sectional view of a polymer light emitting diode in accordance with a second embodiment of the present invention.

As shown in FIG. 2, the polymer light emitting diode 10 in accordance with the second embodiment differs from the polymer light emitting diode 10 in accordance with the first embodiment in that the polymer light emitting diode 10 of this embodiment comprises a hole transporting layer 13a in place of the hole injecting layer 13 so as to improve transporting capacity of holes.

Accordingly, the polymer light emitting diode 10 in accordance with the second embodiment is identical with the polymer light emitting diode 10 in accordance with the first embodiment except that the hole transporting layer 13a in place of the hole injecting layer 13 is formed between the anode layer 12 and the interinsulation layer 14. Further, a process for fabricating the above polymer light emitting diode 10 in accordance with the second embodiment is identical with the process for fabricating the polymer light emitting diode 10 in accordance with the first embodiment except that the process for fabricating the polymer light emitting diode 10 in accordance with this embodiment comprises forming the hole transporting layer 13a in place of the hole injecting layer 13 on the anode layer 12 and then forming the interinsulation layer 14 on the hole transporting layer 13a. In order to avoid repetition, the detailed description of the polymer light emitting diode and the method for fabricating the same in accordance with the second embodiment will be omitted.

FIG. 3 is a sectional view of a polymer light emitting diode in accordance with a third embodiment of the present invention.

As shown in FIG. 3, the polymer light emitting diode 10 in accordance with the third embodiment is identical with the polymer light emitting diode 10 in accordance with the first embodiment except that the polymer light emitting diode 10 of this embodiment further comprises the hole transporting layer 13a formed between the interinsulation layer 14 and the light emitting polymer layer 15.

Further, a process for fabricating the above polymer light emitting diode 10 in accordance with the third embodiment is identical with the process for fabricating the polymer light emitting diode 10 in accordance with the first embodiment except that the process for fabricating the polymer light emitting diode 10 in accordance with this embodiment comprises forming the hole transporting layer 13a between the interinsulation layer 14 and the light emitting polymer layer 15. In order to avoid repetition, the detailed description of the polymer light emitting diode and the method for fabricating the same in accordance with the third embodiment will be omitted.

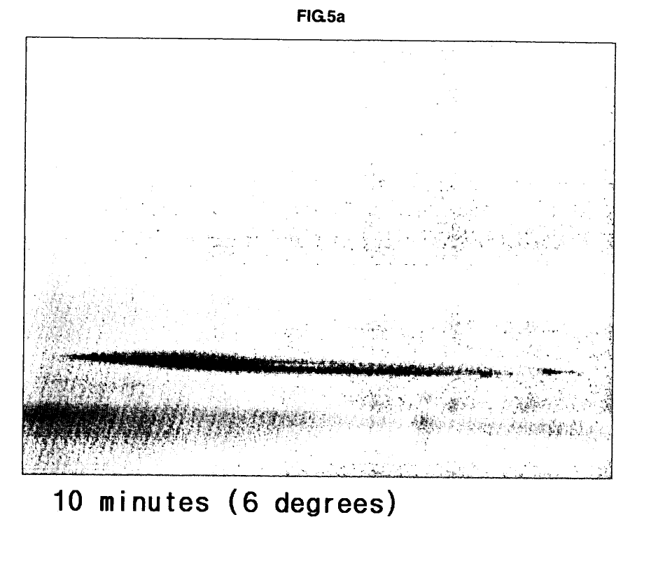

FIG. 4 is a sectional view of a polymer light emitting diode in accordance with a fourth embodiment of the present invention.

As shown in FIG. 4, the polymer light emitting diode 10 in accordance with the fourth embodiment is identical with the polymer light emitting diode 10 in accordance with the first embodiment except that the polymer light emitting diode 10 of this embodiment further comprises the hole transporting layer 13a formed between the hole injecting layer 13 and the interinsulation layer 14.

Further, a process for fabricating the above polymer light emitting diode 10 in accordance with the fourth embodiment is identical with the process for fabricating the polymer light emitting diode 10 in accordance with the first embodiment except that the process for fabricating the polymer light emitting diode in accordance with this embodiment comprises forming the hole transporting layer 13a between the hole injecting layer 13 and the interinsulation layer 14. In order to avoid repetition, the detailed description of the polymer light emitting diode and the method for fabricating the same in accordance with the fourth embodiment will be omitted.

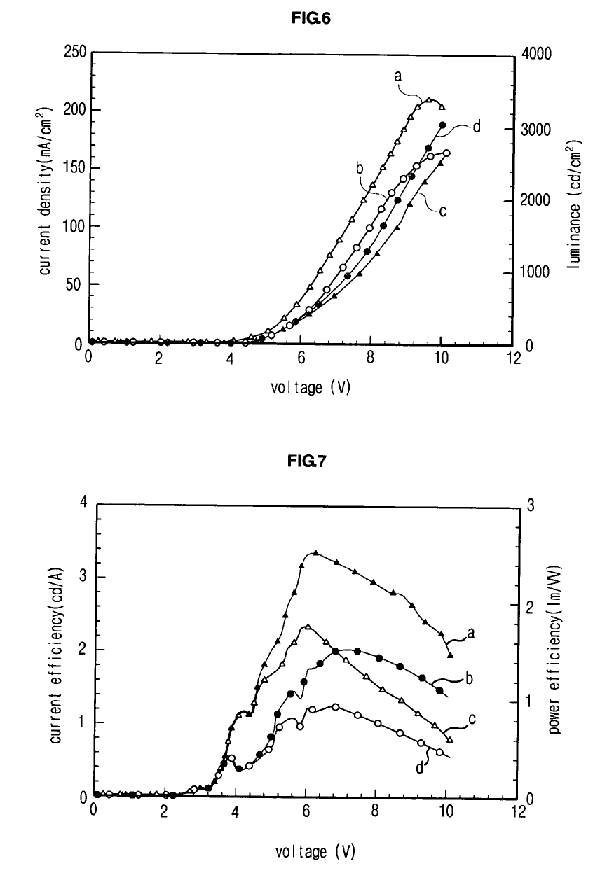

FIG. 6 illustrates graphs representing the relation among current, voltage and luminance of a polymer light emitting diode with an OTS interinsulation layer in accordance with the present invention and a polymer light emitting diode without an OTS interinsulation layer. The polymer light emitting diode without the OTS interinsulation layer had the maximal luminance of 2,659 cd/m² at a voltage of 10V (with reference to graph “b”), and the polymer light emitting diode with the OTS interinsulation layer had the maximal luminance of 3,443 cd/m² at a voltage of 9.8V (with reference to graph “a”).

However, as shown in FIG. 6, the electric current density of the polymer light emitting diode with the OTS interinsulation layer (with reference to graph “c”) was lower than the electric current density of the polymer light emitting diode without the OTS interinsulation layer (with reference to graph “d”).

That is, the polymer light emitting diode with the OTS interinsulation layer had an electric current density lower than that of the polymer light emitting diode without the OTS interinsulation layer at the same voltage, and had a luminance higher than that of the polymer light emitting diode without the OTS interinsulation layer at the same voltage.

FIG. 7 illustrates graphs representing current efficiency and power efficiency in proportion to voltage of a polymer light emitting diode with an OTS interinsulation layer in accordance with the present invention and a polymer light emitting diode without an OTS interinsulation layer.

The polymer light emitting diode without the OTS interinsulation layer exhibited the maximal current efficiency of 2.0 cd/A at a voltage of 7.2V (with reference to graph “b”), and exhibited the maximal power efficiency of 0.91 m/W at a voltage of 6.6V (with reference to graph “d”). Further, the polymer light emitting diode with the OTS interinsulation layer exhibited the maximal current efficiency of 3.4 cd/A at a voltage of 6.0V (with reference to graph “a”), and exhibited the maximal power efficiency of 1.81 m/W at the same voltage (with reference to graph “c”).

As described above, the polymer light emitting diode having the interinsulation layer in accordance with the present invention had improved operating characteristics approximately twice those of a general polymer light emitting diode.

As apparent from the above description, the present invention provides a polymer light emitting diode having an interinsulation layer, which has operating characteristics at least twice those of a general polymer light emitting diode and is used as a back-light of a TFT-LCD and a light emitting device of an active-matrix polymer light emitting display, and a method for fabricating the same.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A polymer light emitting diode having an interinsulation layer comprising:
a hole injecting layer formed on an anode layer, formed on a glass substrate, by coating or printing;
the interinsulation layer having a designated thickness formed on the hole injecting layer;
a light emitting polymer layer formed on the interinsulation layer by coating or printing; and
an electron injecting layer formed on the light emitting polymer layer, and a cathode layer formed on the electron injecting layer.

2. A polymer light emitting diode having an interinsulation layer comprising:
a hole transporting layer formed on an anode layer, formed on a glass substrate, by coating or printing;
the interinsulation layer having a designated thickness formed on the hole transporting layer;
a light emitting polymer layer formed on the interinsulation layer by coating or printing; and
an electron injecting layer formed on the light emitting polymer layer, and a cathode layer formed on the electron injecting layer.

3. A polymer light emitting diode having an interinsulation layer comprising:
a hole injecting layer formed on an anode layer, formed on a glass substrate, by coating or printing;
the interinsulation layer having a designated thickness formed on the hole injecting layer;
a hole transporting layer formed on the interinsulation layer by coating or printing;
a light emitting polymer layer formed on the hole transporting layer by coating or printing; and
an electron injecting layer formed on the light emitting polymer layer, and a cathode layer formed on the electron injecting layer.

4. The polymer light emitting diode as set forth in claim 1, further comprising a hole transporting layer formed between the hole injecting layer and the interinsulation layer,
wherein the interinsulation layer is formed by SAM treatment.

5. The polymer light emitting diode as set forth in any one of claims 1 to 4, wherein the interinsulation layer is made of an organic material.

6. The polymer light emitting diode as set forth in claim 5, wherein the organic material is octadecyltrichlorosilane (OTS).

7. The polymer light emitting diode as set forth in claim 6, wherein the interinsulation layer is formed by SAM treatment.

8. A method for fabricating a polymer light emitting diode having an interinsulation layer comprising:
forming a hole injecting layer on an anode layer, formed on a glass substrate, by coating or printing;
forming the interinsulation layer having a designated thickness on the hole injecting layer;
forming a light emitting polymer layer on the interinsulation layer by coating or printing; and
sequentially forming an electron injecting layer and a cathode layer on the light emitting polymer layer.

9. A method for fabricating a polymer light emitting diode having an interinsulation layer comprising:
forming a hole transporting layer on an anode layer, formed on a glass substrate, by coating or printing;
forming the interinsulation layer having a designated thickness on the hole transporting layer;
forming a light emitting polymer layer on the interinsulation layer by coating or printing; and
sequentially forming an electron injecting layer and a cathode layer on the light emitting polymer layer.

10. A method for fabricating a polymer light emitting diode having an interinsulation layer comprising:
forming a hole injecting layer on an-anode layer, formed on a glass substrate, by coating or printing;
forming the interinsulation layer having a designated thickness on the hole injecting layer;
forming a hole transporting layer on the interinsulation layer by coating or printing;
forming a light emitting polymer layer on the hole transporting layer by coating or printing; and
sequentially forming an electron injecting layer and a cathode layer on the light emitting polymer layer.

11. The method as set forth in claim 8, further comprising forming a hole transporting layer on the hole injecting layer by coating or printing before the formation of the interinsulation layer on the hole injecting layer.

12. The method as set forth in any one of claims 8 to 11, wherein the interinsulation layer is formed by SAM treatment using a solution.

13. The method as set forth in claim 12, wherein the interinsulation layer has a mono-layered structure, and is formed by SAM treatment using an OTS solution.

14. The method as set forth in claim 13, wherein the OTS solution has a concentration of 10˜100 mM.

15. The method as set forth in claim 13, wherein the interinsulation layer has a thickness of 0.5˜5□.

16. The method as set forth in claim 13, wherein the interinsulation layer contains oxygen or carbon.

17. The method as set forth in claim 12, wherein the interinsulation layer has at least a double-laminated structure, and is formed by repeating SAM treatment at least twice using only an OTS solution or using the OTS solution and at least one other solution enabling the SAM treatment.

18. The method as set forth in claim 17, wherein the OTS solution and at least one other solution enabling the SAM treatment each has a concentration of 10˜100 mM.

19. The method as set forth in claim 17, wherein the interinsulation layer has a thickness of 0.5˜5 nm.

20. The method as set forth in claim 17, wherein the interinsulation layer contains oxygen or carbon.
